(19) United States
(12) Patent Application Publication
(10) Pub. No.: US 2026/0251603 A1
(43) Pub. Date: Aug. 27, 2026

(54) METHOD FOR MANUFACTURING SENSOR AND SENSOR

(71) Applicant: KABUSHIKI KAISHA TOSHIBA, Kawasaki-shi (JP)

(72) Inventor: Yoshiaki SUGIZAKI, Fujisawa Kanagawa (JP)

(73) Assignee: KABUSHIKI KAISHA TOSHIBA, Kawasaki-shi (JP)

(21) Appl. No.: 19/415,966

(22) Filed: Dec. 11, 2025

(30) Foreign Application Priority Data
Feb. 21, 2025 (JP) 2025-026872

(51) Int. Cl. G01N 27/12; B81C 1/00

(52) U.S. Cl. CPC G01N 27/128; B81C 1/00119; G01N 27/125; B81C 2201/0132; B81C 2201/0181

(57) ABSTRACT

According to one embodiment, a method for manufacturing a sensor includes performing a first process to form a first structure on a base. The first structure includes a first electrode, a first counter electrode, a first layer-shaped portion provided between the base and the first electrode and between the base and the first counter electrode, and a first sacrificial layer provided between the base and the first layer-shaped portion. The method includes performing a second process to form a first metal oxide layer being in contact with the first electrode and the first counter electrode. The method includes performing a sacrificial layer removal process to remove the first sacrificial layer by a treatment in an atmosphere including oxygen plasma after the second process.

### CROSS-REFERENCE TO RELATED APPLICATIONS

This application is based upon and claims the benefit of priority from Japanese Patent Application No. 2025-026872, filed on Feb. 21, 2025; the entire contents of which are incorporated herein by reference.

### FIELD

Embodiments described herein relate generally to a method for manufacturing a sensor and a sensor.

### BACKGROUND

For example, there is a sensor for detecting a detection target such as gas, etc. In the sensors, improvement of the characteristics is desired.

### BRIEF DESCRIPTION OF THE DRAWINGS

FIG. 1 is a flow chart illustrating a method for manufacturing a sensor according to a first embodiment;

FIGS. 2A to 2C are schematic cross-sectional views illustrating the method for manufacturing the sensor according to the first embodiment;

FIGS. 3A and 3B are schematic cross-sectional views illustrating the method for manufacturing the sensor according to the first embodiment;

FIG. 4 is a schematic plan view illustrating the sensor according to the embodiment;

FIG. 5 is a schematic cross-sectional view illustrating the sensor according to the embodiment;

FIG. 6 is a schematic cross-sectional view illustrating the sensor according to the embodiment; and

FIG. 7 is a schematic cross-sectional view illustrating the sensor according to the embodiment.

### DETAILED DESCRIPTION

According to one embodiment, a method for manufacturing a sensor includes performing a first process to form a first structure on a base. The first structure includes a first electrode, a first counter electrode, a first layer-shaped portion provided between the base and the first electrode and between the base and the first counter electrode, and a first sacrificial layer provided between the base and the first layer-shaped portion. The method includes performing a second process to form a first metal oxide layer being in contact with the first electrode and the first counter electrode. The method includes performing a sacrificial layer removal process to remove the first sacrificial layer by a treatment in an atmosphere including oxygen plasma after the second process.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

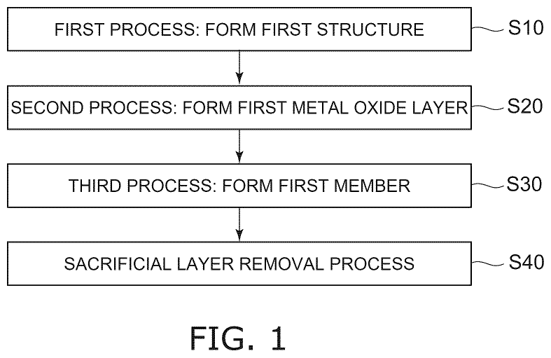

FIG. 1 is a flow chart illustrating a method for manufacturing a sensor according to a first embodiment.

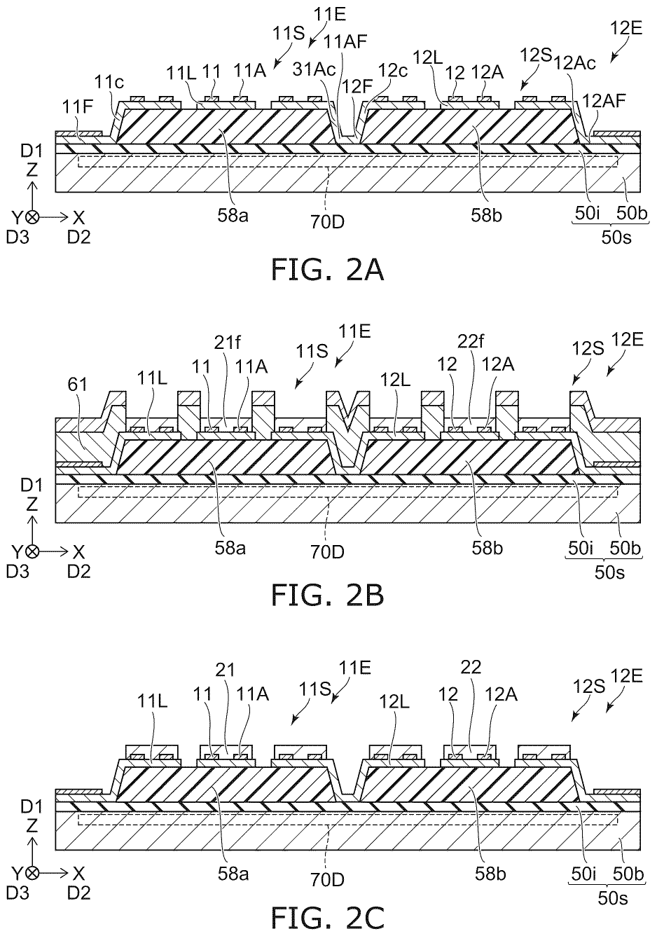

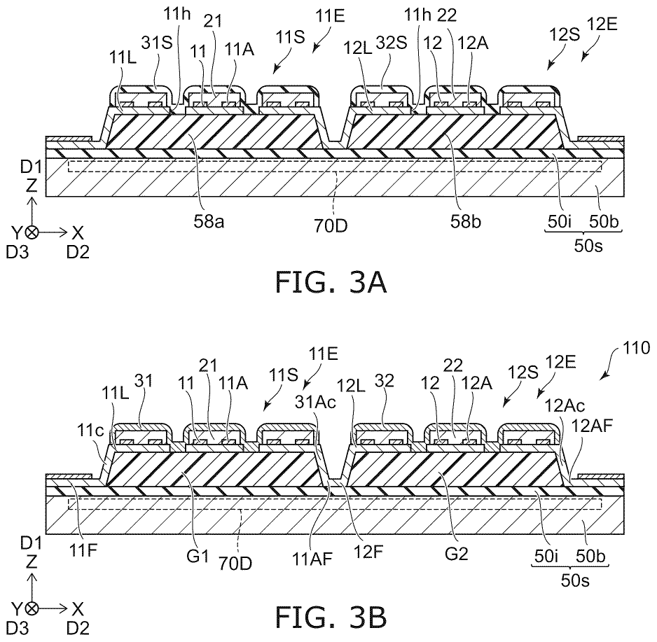

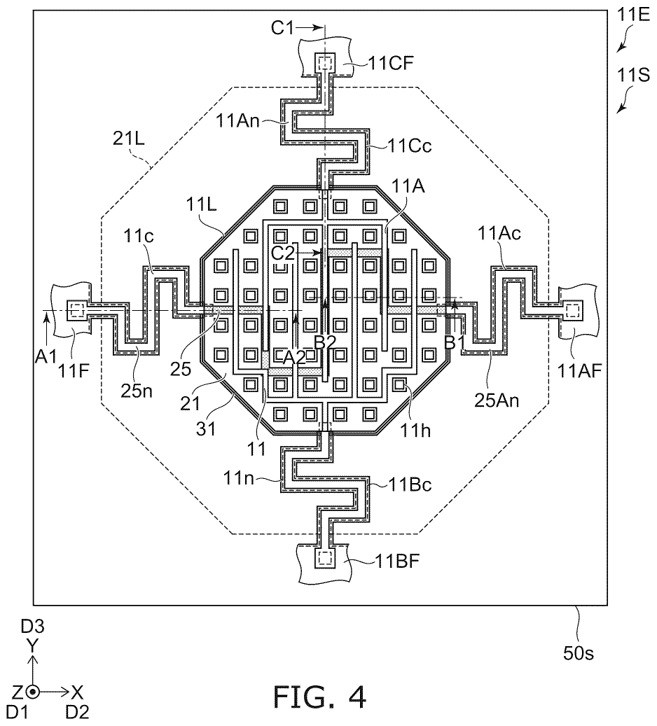

FIGS. 2A to 2C, 3A and 3B are schematic cross-sectional views illustrating the method for manufacturing the sensor according to the first embodiment.

As shown in FIGS. 1 and 2A, a first process is performed to form a first structure 11S on a base 50s (step S10). At least a part of the first structure 11S becomes a first element portion 11E.

A first direction D1 from the base 50s to the first structure 11S is defined as a Z-axis direction. One direction perpendicular to the Z-axis direction is defined as an X-axis direction. A direction perpendicular to the Z-axis direction and the X-axis direction is defined as a Y-axis direction.

The base 50s includes, for example, a substrate 50b and an insulating layer 50i. The substrate 50b may include, for example, a semiconductor substrate. The insulating layer 50i is provided on the substrate 50b. The substrate 50b may include an electric circuit 70D. At least a part of the electric circuit 70D may be configured to control, for example, the first element portion 11E. At least a part of the electric circuit 70D may be configured to process a signal obtained from the first element portion 11E.

The first structure 11S includes a first electrode 11, a first counter electrode 11A, a first layer-shaped portion 11L, and a first sacrificial layer 58a. The first layer-shaped portion 11L is provided between the base 50s and the first electrode 11, and between the base 50s and the first counter electrode 11A. The first layer-shaped portion 11L extends, for example, along the X-Y plane. The first sacrificial layer 58a is provided between the base 50s and the first layer-shaped portion 11L. The first layer-shaped portion 11L is an insulating layer.

The first structure 11S may be obtained by forming the first sacrificial layer 58a on the base 50s, and forming the first layer-shaped portion 11L, the first electrode 11, and the first counter electrode 11A on the first sacrificial layer 58a.

As shown in FIGS. 1, 2B and 2C, a second process is performed to form a first metal oxide layer 21 being in contact with the first electrode 11 and the first counter electrode 11A (step S20).

As shown in FIG. 2B, in this example, a resist layer 61 having the desired pattern shape is formed, and a first metal oxide film 21f that will become the first metal oxide layer 21 is formed on the entire surface including the top of the resist layer 61.

As shown in FIG. 2C, the resist layer 61 is removed. Thereby, the first metal oxide layer 21 having the desired pattern shape is obtained.

As shown in FIG. 1, after the second process, a sacrificial layer removal process is performed to remove the first sacrificial layer 58a by treatment in an atmosphere including oxygen plasma (step S40).

This allows the first metal oxide layer 21 in contact with the first electrode 11 and the first counter electrode 11A to be efficiently formed. This allows the sensor 110 according to the embodiment to be obtained.

The first sacrificial layer 58a may include an organic substance. The first sacrificial layer 58a is effectively removed by treatment in an atmosphere including oxygen plasma. The first metal oxide layer 21 is not corroded or etched by the treatment in an atmosphere including oxygen plasma. The desired structure is stably obtained. A manufacturing method can be provided that allows the efficient manufacture of a sensor with improved characteristics.

In the embodiment, the first electrical resistance between the first electrode 11 and the first counter electrode 11A is configured to change according to a state of a first detection target. For example, the first detection target is present around the first element portion 11E. The change in the first electrical resistance may be caused by a change in the characteristics (e.g., electrical conductivity, etc.) of the first metal oxide layer 21 due to the first detection target.

The first detection target may include at least one selected from the group consisting of, for example, hydrogen, methane, carbon monoxide, nitrogen oxides, ethanol, formaldehyde, other volatile organic compounds (VOCs), and odor molecules. The sensor 110 is, for example, a gas sensor. The sensor 110 may be, for example, an odor sensor.

The treatment in the atmosphere including oxygen plasma includes, for example, oxygen ashing. At least a part of the first sacrificial layer 58a may be removed through a first hole 11h provided in the first layer-shaped portion 11L.

The second process for forming the first metal oxide layer 21 may include, for example, forming the first metal oxide layer 21 by sputtering. The first metal oxide layer 21 is formed efficiently. The first metal oxide layer 21 includes at least one selected from the group consisting of tin oxide, zinc oxide, titanium oxide, indium oxide, and tungsten oxide. The first detection target can be detected with high sensitivity.

As shown in FIG. 1, after the second process and before the sacrificial layer removal process, a third process may be performed (step S30). The third process includes forming a first member 31 on the first metal oxide layer 21 (see FIG. 3B). The first member 31 includes a first element and a first material. The sacrificial layer removal process includes removing at least a part of the first material.

After the sacrificial layer removal process, the first element remains on the first metal oxide layer 21. By the remaining of the first element, a change in the first electrical resistance in the state of the first detection target occurs more effectively. For example, the first element may function as a catalyst.

The first element may include at least one selected from the group consisting of platinum, palladium, titanium, rhodium, strontium, magnesium, manganese, zinc, iron, cobalt, nickel, bismuth, aluminum, selenium, germanium, and silicon. A change in the first electrical resistance is effectively obtained.

As shown in FIG. 3A, the formation of the first member 31 may include applying a first solution 31S including the first element and the first material on the first metal oxide layer 21. The first member 31 can be efficiently formed. As described below, members including different types of elements can be efficiently formed.

The first member 31 may include a solvent in addition to the first element and the first material. The solvent may be included in the first material. The formation of the first member 31 may include solidifying at least a part of the first solution 31S. For example, a heat treatment may be performed. For example, the viscosity of the first solution 31S may be increased. For example, the first solution 31S may have thixotropy. For example, a reaction of the first material may occur.

The first material may include at least one selected from the group consisting of an oligomer and a polymer. For example, the first material may be one of a thermosetting resin or a photocurable resin. For example, the first material may include at least one selected from the group consisting of a linear organic portion and a fibrous organic portion.

The first element may be in at least one form selected from the group consisting of, for example, alkoxide, acetonate, chelate, carboxylate, organometallic compound, and fine particles. The organometallic compound may include, for example, at least one selected from the group consisting of triphenylbismuthine, triphenylantimony, triphenylgermanium hydride, tetra-n-butyltin, diphenyldiselenide, diphenylditelluride, and trimethylaluminum. The fine particles include a metal or a metal compound. The metal compound may include at least one selected from the group consisting of a single oxide, a perovskite-type metal oxide, a spinel-type metal oxide, and a hexaaluminate. The first element may be dissolved in the first material. The first element may be dispersed in the first material, and the first solution 31S may be in a paste form. The first solution 31S in such a form can be selectively applied on a desired position. The first solution applied on the desired position (i.e., on the first metal oxide layer 21) is transformed into a catalyst layer in the subsequent sacrificial layer removal step, and is left uniformly and thinly on the face of the first metal oxide layer 21.

As shown in FIG. 2A, the first process may further include forming a second structure 12S on the base 50s. The second structure 12S includes a second electrode 12, a second counter electrode 12A, a second layer-shaped portion 12L, and a second sacrificial layer 58b. The second layer-shaped portion 12L is provided between the base 50s and the second electrode 12, and between the base 50s and the second counter electrode 12A. The second sacrificial layer 58b is provided between the base 50s and the second layer-shaped portion 12L. The second layer-shaped portion 12L is an insulating layer. The second sacrificial layer 58b may include a material included in the first sacrificial layer 58a.

As shown in FIG. 2C, the second process may include forming a second metal oxide layer 22 being in contact with the second electrode 12 and the second counter electrode 12A. The second metal oxide layer 22 may be formed by, for example, sputtering. The second metal oxide layer 22 may include the same material as the material included in the first metal oxide layer 21. The second metal oxide layer 22 may be formed simultaneously with the first metal oxide layer 21.

As shown in FIG. 3B, the sacrificial layer removal process may further include removing the second sacrificial layer 58b. At least a part of the second sacrificial layer 58b may be removed through a second hole 12h provided in the second layer-shaped portion 12L.

After the sacrificial layer removal process, a first gap G1 is formed between the base 50s and the first layer-shaped portion 11L. A second gap G2 is formed between the base 50s and the second layer-shaped portion 12L. This suppresses the transfer of heat between the first structure 11S and the second structure 12S and the base 50s, which has a large heat capacity.

For example, a heating mechanism may be provided for the first structure 11S and the second structure 12S. Since the heat capacity of the first structure 11S and the second structure 12S is small, the first structure 11S and the second structure 12S can be heated with small power consumption. As the heating mechanism, a high resistance wiring may be formed, and power may be newly applied to the high resistance wiring. As the heating mechanism, power may be applied between the first electrode 11 and the first counter electrode 11A. Power may be supplied to the first metal oxide layer 21. As the heating mechanism, power may be applied between the second electrode 12 and the second counter electrode 12A. Power may be supplied to the second metal oxide layer 22.

The second electrical resistance between the second electrode 12 and the second counter electrode 12A is configured to change depending on a state of a second detection target. For example, the second detection target is present around the second element portion 12E. The change in the second electrical resistance may be due to a change in a property (e.g., electrical conductivity) of the second metal oxide layer 22 caused by the second detection target.

For example, by processing first information based on the first electrical resistance and second information based on the second electrical resistance, detection with higher accuracy is possible.

The second detection target may be the same as the first detection target. The second detection target may be different from the first detection target. By detecting the states of different types of detection targets, the state of at least one of the first detection target and the second detection target can be detected with higher accuracy.

As shown in FIG. 3B, the third process may further include forming a second member 32 on the second metal oxide layer 22. The second member 32 includes a second element and a second material. The sacrificial layer removal process may include removing at least a part of the second material. The second element is different from the first element.

After the sacrificial layer removal process, the second element remains on the second metal oxide layer 22. By leaving the second element, a change in the second electrical resistance in the state of the second detection target occurs more effectively. For example, the second element may function as a catalyst. A detection result with higher accuracy is obtained.

As already explained, the formation of the first member 31 may include applying the first solution 31S including the first element and the first material on the first metal oxide layer 21. The formation of the second member 32 may include applying a second solution 32S including the second element and the second material on the second metal oxide layer 22. For example, the first solution 31S and the second solution 32S including different elements are efficiently applied on the desired position by an inkjet method or the like.

The first metal oxide layer 21 may include an oxide including at least one selected from the group consisting of calcium, strontium, barium, and radium. The first metal oxide layer 21 may further include carbon. The second metal oxide layer 22 may include the same material as the first metal oxide layer 21.

As shown in FIG. 2A, the first structure 11S may further include a first fixed portion 11F fixed to the base 50s. As shown in FIG. 3B, after the sacrificial layer removal process, the first fixed portion 11F supports the first layer-shaped portion 11L.

As shown in FIG. 2A, the first structure 11S may further include a first counter fixed portion 11AF fixed to the base 50s. As shown in FIG. 3B, after the sacrificial layer removal process, the first counter fixed portion 11AF supports the first layer-shaped portion 11L.

As shown in FIG. 2A, the second structure 12S may further include a second fixed portion 12F fixed to the base 50s. As shown in FIG. 3B, after the sacrificial layer removal process, the second fixed portion 12F supports the second layer-shaped portion 12L.

As shown in FIG. 2A, the second structure 12S may further include a second counter fixed portion 12AF fixed to the base 50s. As shown in FIG. 3B, after the sacrificial layer removal process, the second counter fixed portion 12AF supports the second layer-shaped portion 12L.

The first structure 11S may further include a first connecting portion 11c and a first counter connecting portion 11Ac. The first connecting portion 11c is provided between the first fixed portion 11F and the first layer-shaped portion 11L. The first counter connecting portion 11Ac is provided between the first counter fixed portion 11AF and the first layer-shaped portion 11L.

The second structure 12S may further include a second connecting portion 12c and a second counter connecting portion 12Ac. The second connecting portion 12c is provided between the second fixed portion 12F and the second layer-shaped portion 12L. The second counter connecting portion 12Ac is provided between the second counter fixed portion 12AF and the second layer-shaped portion 12L.

### Second Embodiment

The second embodiment relates to a sensor. As shown in FIG. 3B, the sensor 110 according to the embodiment includes the base 50s, the first element portion 11E, and the second element portion 12E.

The first element portion 11E includes the first member 31, the first structure 11S, and the first metal oxide layer 21. The first member 31 includes the first element. The first structure 11S is provided between the base 50s and the first member 31. The first metal oxide layer 21 is provided between the first structure 11S and the first member 31.

The first structure 11S includes the first electrode 11, the first counter electrode 11A, and the first layer-shaped portion 11L. The first electrode 11 and the first counter electrode 11A are provided between the base 50s and the first member 31. The first layer-shaped portion 11L is provided between the base 50s and the first electrode 11, and between the base 50s and the first counter electrode 11A.

The first gap G1 is provided between the base 50s and the first layer-shaped portion 11L. The first metal oxide layer 21 contacts the first electrode 11 and the first counter electrode 11A.

The second element portion 12E includes the second member 32, the second structure 12S, and the second metal oxide layer 22. The second member 32 includes the second element. The second structure 12S is provided between the base 50s and the second member 32. The second metal oxide layer 22 is provided between the second structure 12S and the second member 32.

The second structure 12S includes the second electrode 12, the second counter electrode 12A, and the second layer-shaped portion 12L. The second electrode 12 and the second counter electrode 12A are provided between the base 50s and the second member 32. The second layer-shaped portion 12L is provided between the base 50s and the second electrode 12, and between the base 50s and the second counter electrode 12A.

The second gap G2 is provided between the base 50s and the second layer-shaped portion 12L. The second metal oxide layer 22 contacts the second electrode 12 and the second counter electrode 12A. The second element is different from the first element.

For example, the first electrical resistance between the first electrode 11 and the first counter electrode 11A is configured to change depending on the state of the first detection object. For example, the second electrical resistance between the second electrode 12 and the second counter electrode 12A is configured to change depending on the state of the second detection object.

As described above, the second element included in the second member 32 is different from the first element included in the first member 31. This makes it possible to detect, for example, different types of detection targets. For example, by processing the first information based on the first electrical resistance and the second information based on the second electrical resistance, detection with higher accuracy is possible. It is possible to provide a sensor with improved characteristics.

At least one of the first element and the second element may include at least one selected from the group consisting of platinum, palladium, titanium, rhodium, strontium, magnesium, manganese, zinc, iron, cobalt, nickel, bismuth, aluminum, selenium, germanium, and silicon. At least one of the first element and the second element may be in at least one form selected from the group consisting of a single oxide, a perovskite metal oxide, a spinel metal oxide, and a hexaaluminate. A part of the first element and the second element may be oxidized by the oxygen plasma used in the sacrificial layer removal process. At least one of the first metal oxide layer 21 and the second metal oxide layer 22 may include at least one selected from the group consisting of tin oxide, zinc oxide, titanium oxide, indium oxide, and tungsten oxide.

Below, examples according to the embodiment will be described.

FIG. 4 is a schematic plan view illustrating the sensor according to the embodiment.

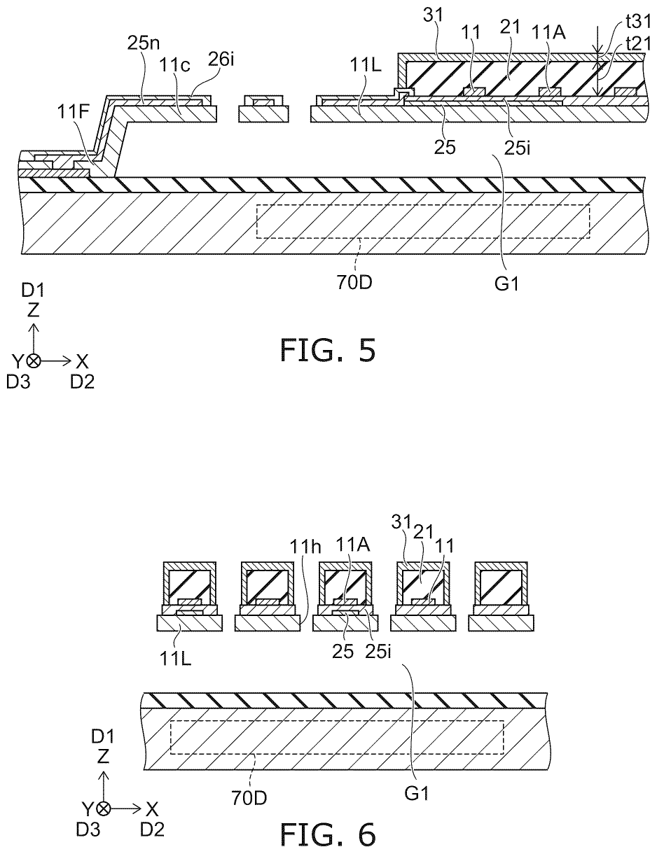

FIGS. 5 to 7 are schematic cross-sectional views illustrating sensors according to the embodiment.

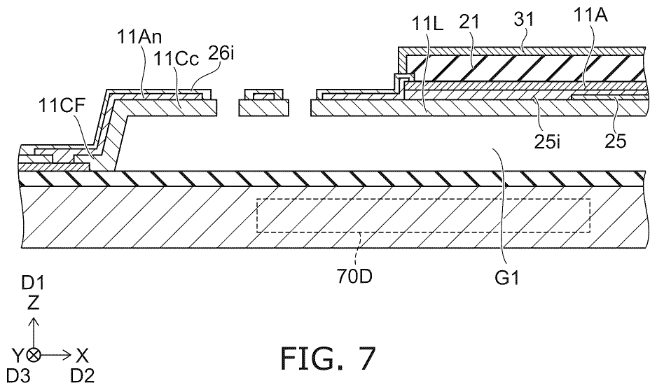

FIG. 5 is a cross-sectional view taken along the line A1-A2 in FIG. 4. FIG. 6 is a cross-sectional view taken along the line B1-B2 in FIG. 4. FIG. 7 is a cross-sectional view taken along the line C1-C2 in FIG. 4.

As shown in FIG. 4, in the sensor 110 according to the embodiment, the first structure 11S includes a first other fixed portion 11BF and a first counter other fixed portion 11CF in addition to the first fixed portion 11F and the first counter fixed portion 11AF. The first other fixed portion 11BF and the first counter other fixed portion 11CF are fixed to the base 50s.

A second direction D2 from the first fixed portion 11F to the first counter fixed portion 11AF crosses a third direction D3 from the first other fixed portion 11BF to the first counter other fixed portion 11CF.

The first structure 11S includes a first other connecting portion 11Bc and a first counter other connecting portion 11Cc in addition to the first connecting portion 11c and the first counter connecting portion 11Ac. The first other connecting portion 11Bc is provided between the first other fixed portion 11BF and the first layer-shaped portion 11L. The first counter other connecting portion 11Cc is provided between the first counter other fixed portion 11CF and the first layer-shaped portion 11L.

At least one of the first connecting portion 11c, the first counter connecting portion 11Ac, the first other connecting portion 11Bc, and the first counter other connecting portion 11Cc may have a meandering structure. These connecting portions function as spring portions. Thermal conduction is suppressed.

The first structure 11S may include a first wiring 11n and a first counter wiring 11An. The first wiring 11n is electrically connected to the first electrode 11. The first counter wiring 11An is electrically connected to the first counter electrode 11A.

The first wiring 11n may pass through one of the multiple connecting portions. The first counter wiring 11An may pass through another one of the multiple connecting portions. In this example, the first wiring 11n passes through the first other connecting portion 11Bc. The first counter wiring 11An passes through the first counter other connecting portion 11Cc.

A first metal oxide layer 21 is formed on the upper face including the first electrode 11 and the first counter electrode 11A. The first member 31 is formed on the first metal oxide layer 21.

As shown in FIG. 4, the first structure 11S may include a first conductive member 25. The first structure 11S is configured such that the temperature of the first structure 11S increases with power supplied to the first conductive member 25. The first conductive member 25 is, for example, a heater.

The first structure 11S may include a first conductive wiring 25n and a first counter conductive wiring 25An. The first conductive wiring 25n is electrically connected to a part of the first conductive member 25. The first counter conductive wiring 25An is electrically connected to another part of the first conductive member 25. The first conductive wiring 25n may pass through one of the multiple connecting portions. The first counter conductive wiring 25An may pass through another one of the multiple connecting portions. In this example, the first conductive wiring 25n passes through the first connecting portion 11c. The first counter conductive wiring 25An passes through the first counter connecting portion 11Ac.

As shown in FIGS. 5 to 7, the first structure 11S may include an intermediate insulating layer 25i. The intermediate insulating layer 25i is provided between the first conductive member 25 and the first electrode 11, and between the first conductive member 25 and the first counter electrode 11A.

The first structure 11S may include an upper insulating layer 26i. The wiring is provided between the connecting portion and the upper insulating layer 26i.

The first layer-shaped portion 11L may include a first hole 11h. At least a part of the first sacrificial layer 58a may be removed through the first hole 11h.

As shown in FIG. 5, a thickness of the first metal oxide layer 21 along the first direction D1 is defined as a first metal oxide layer thickness t21. The first metal oxide layer thickness t21 is, for example, not less than 50 nm and not more than 1000 nm.

As shown in FIG. 5, a thickness of the first member 31 along the first direction D1 is defined as the first member thickness t31. The first member thickness t31 is, for example, not less than 0.5 nm and not more than 1000 nm. The first member 31 may be, for example, island-shaped or mesh-shaped.

The embodiments may include the following Technical proposals:

### Technical Proposal 1

A method for manufacturing a sensor, the method comprising:
performing a first process to form a first structure on a base, the first structure including:
   a first electrode;
   a first counter electrode;
   a first layer-shaped portion provided between the base and the first electrode and between the base and the first counter electrode; and
   a first sacrificial layer provided between the base and the first layer-shaped portion,
performing a second process to form a first metal oxide layer being in contact with the first electrode and the first counter electrode; and
performing a sacrificial layer removal process to remove the first sacrificial layer by a treatment in an atmosphere including oxygen plasma after the second process.

### Technical Proposal 2)

The method for manufacturing the sensor according to Technical proposal 1, further comprising:
performing a third process after the second process and before the sacrificial layer removal process to form a first member on the first metal oxide layer,
the first member including a first element and a first material, and
the sacrificial layer removal process includes removing at least a part of the first material.

### Technical Proposal 3

The method for manufacturing the sensor according to Technical proposal 2, wherein
the forming the first member includes applying a first solution including the first element and the first material on an upper face including the first metal oxide layer.

### Technical Proposal 4

The method for manufacturing the sensor according to Technical proposal 3, wherein
the forming the first member includes solidifying at least a part of the first solution.

### Technical Proposal 5

The method for manufacturing the sensor according to any one of Technical proposals 2-4, wherein the first element includes at least one selected from the group consisting of platinum, palladium, titanium, rhodium, strontium, magnesium, manganese, zinc, iron, cobalt, nickel, bismuth, aluminum, selenium, germanium, and silicon, or constitutes at least one form selected from the group consisting of a single oxide, a perovskite-type metal oxide, a spinel-type metal oxide, and a hexaaluminate.

### Technical Proposal 6

The method for manufacturing the sensor according to any one of Technical proposals 2-5, wherein the first material includes at least one selected from the group consisting of a thermosetting resin and a photocurable resin.

### Technical Proposal 7

The method for manufacturing the sensor according to any one of Technical proposals 2-5, wherein the first material includes at least one selected from the group consisting of oligomers and polymers.

### Technical Proposal 8

The method for manufacturing the sensor according to any one of Technical proposals 2-5, wherein the first material includes at least one selected from the group consisting of a linear organic portion and a fibrous organic portion.

### Technical Proposal 9

The method for manufacturing the sensor according to any one of Technical proposals 2-5, wherein the first element is in at least one form selected from the group consisting of alkoxides, acetonates, chelates, carboxylates, organometallic associations, metal particles, and metal compound particles.

### Technical Proposal 10

The method for manufacturing the sensor according to any one of Technical proposals 1-9, wherein
the first metal oxide layer includes at least one selected from the group consisting of tin oxide, zinc oxide, titanium oxide, indium oxide, and tungsten oxide.

### Technical Proposal 11

The method for manufacturing the sensor according to any one of Technical proposals 1-10, wherein
a first electrical resistance between the first electrode and the first counter electrode is configured to change according to a state of a first detection target.

### Technical Proposal 12

The method for manufacturing the sensor according to Technical proposal 2, wherein
the first process further includes forming a second structure on the base,
the second structure includes:
   a second electrode;
   a second counter electrode;
   a second layer-shaped portion provided between the base and the second electrode and between the base and the second counter electrode; and
   a second sacrificial layer provided between the base and the second layer-shaped portion,
the second process includes forming a second metal oxide layer being in contact with the second electrode and the second counter electrode,
the sacrificial layer removal process further includes removing the second sacrificial layer,
the third process further includes forming a second member on the second metal oxide layer,
the second member includes a second element and a second material,
the sacrificial layer removal process includes removing at least a part of the second material, and
the second element is different from the first element.

### Technical Proposal 13

The method for manufacturing the sensor according to any one of Technical proposals 1-12, wherein
the treatment in the atmosphere including the oxygen plasma includes oxygen ashing.

### Technical Proposal 14

The method for manufacturing the sensor according to any one of Technical proposals 1-13, wherein
the second process includes forming the first metal oxide layer by sputtering.

### Technical Proposal 15

The method for manufacturing the sensor according to any one of Technical proposals 1-14, wherein
the first metal oxide layer includes an oxide including at least one selected from the group consisting of calcium, strontium, barium, and radium, and
the first metal oxide layer further includes carbon.

### Technical Proposal 16

The method for manufacturing the sensor according to any one of Technical proposals 1-15, wherein
the first structure further includes a first fixed portion fixed to the base, and
after the sacrificial layer removal process, the first fixed part supports the first layer-shaped portion.

### Technical Proposal 17

The method for manufacturing the sensor according to Technical proposal 16, wherein
the first structure further includes a first counter fixed portion fixed to the base,
the first counter fixed portion supports the first layer-shaped portion after the sacrificial layer removal process, the first structure further includes:
   a first connecting portion provided between the first fixed portion and the first layer-shaped portion; and
   a first counter connecting portion provided between the first counter fixed portion and the first layer-shaped portion,

### Technical Proposal 18

A sensor, comprising:
a base;
a first element portion; and
a second element portion,
the first element portion including:
   a first member including a first element,
   a first structure provided between the base and the first member; and
   a first metal oxide layer provided between the first structure and the first member,
the first structure including:
   a first electrode and a first counter electrode provided between the base and the first member;
   a first layer-shaped portion provided between the base and the first electrode and between the base and the first counter electrode,
a first gap being provided between the base and the first layer-shaped portion,
the first metal oxide layer being in contact with the first electrode and the first counter electrode,
the second element portion including:
   a second member including a second element,
   a second structure provided between the base and the second member; and
   a second metal oxide layer provided between the second structure and the second member,
the second structure including:
   a second electrode and a second counter electrode provided between the base and the second member; and
   a second layer-shaped portion provided between the base and the second electrode and between the base and the second counter electrode,
a second gap being provided between the base and the second layer-shaped portion,
the second metal oxide layer being in contact with the second electrode and the second counter electrode, and
the second element being different from the first element.

### Technical Proposal 19

The sensor according to Technical proposal 18, wherein
at least one of the first element and the second element includes at least one selected from the group consisting of platinum, palladium, titanium, rhodium, strontium, magnesium, manganese, zinc, iron, cobalt, nickel, bismuth, aluminum, selenium, germanium, and silicon, or constitutes at least one form selected from the group consisting of a single oxide, a perovskite-type metal oxide, a spinel-type metal oxide, and a hexaaluminate.

### Technical Proposal 20

The sensor according to Technical proposal 18 or 19, wherein
a first electrical resistance between the first electrode and the first counter electrode is configured to change depending on a state of a first detection target.

According to the embodiment, a method for manufacturing a sensor and a sensor capable of improving characteristics are provided.

In this specification, “an electrically connected state” includes a state in which multiple conductors are in physical contact with each other and a current flows between these multiple conductors. “An electrically connected state” includes a state in which a conductor is inserted between multiple conductors and a current flows between these multiple conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in sensors such as element portions, structures, electrode, layer-shaped portions, bases, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all methods for manufacturing sensors and all sensors practicable by an appropriate design modification by one skilled in the art based on the methods for manufacturing sensors and the sensors described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a sensor, the method comprising:
performing a first process to form a first structure on a base, the first structure including:
a first electrode;
a first counter electrode;
a first layer-shaped portion provided between the base and the first electrode and between the base and the first counter electrode; and
a first sacrificial layer provided between the base and the first layer-shaped portion,
performing a second process to form a first metal oxide layer being in contact with the first electrode and the first counter electrode; and
performing a sacrificial layer removal process to remove the first sacrificial layer by a treatment in an atmosphere including oxygen plasma after the second process.

2. The method for manufacturing the sensor according to claim 1, further comprising:
performing a third process after the second process and before the sacrificial layer removal process to form a first member on the first metal oxide layer,
the first member including a first element and a first material, and
the sacrificial layer removal process includes removing at least a part of the first material.

3. The method for manufacturing the sensor according to claim 2, wherein
the forming the first member includes applying a first solution including the first element and the first material on an upper face including the first metal oxide layer.

4. The method for manufacturing the sensor according to claim 3, wherein
the forming the first member includes solidifying at least a part of the first solution.

5. The method for manufacturing the sensor according to claim 2, wherein
the first element includes at least one selected from the group consisting of platinum, palladium, titanium, rhodium, strontium, magnesium, manganese, zinc, iron, cobalt, nickel, bismuth, aluminum, selenium, germanium, and silicon, or constitutes at least one form selected from the group consisting of a single oxide, a perovskite-type metal oxide, a spinel-type metal oxide, and a hexaaluminate.

6. The method for manufacturing the sensor according to claim 2, wherein
the first material includes at least one selected from the group consisting of a thermosetting resin and a photocurable resin.

7. The method for manufacturing the sensor according to claim 2, wherein
the first material includes at least one selected from the group consisting of oligomers and polymers.

8. The method for manufacturing the sensor according to claim 2, wherein
the first material includes at least one selected from the group consisting of a linear organic portion and a fibrous organic portion.

9. The method for manufacturing the sensor according to claim 2, wherein
the first element is in at least one form selected from the group consisting of alkoxides, acetonates, chelates, carboxylates, organometallic associations, metal particles, and metal compound particles.

10. The method for manufacturing the sensor according to claim 1, wherein
the first metal oxide layer includes at least one selected from the group consisting of tin oxide, zinc oxide, titanium oxide, indium oxide, and tungsten oxide.

11. The method for manufacturing the sensor according to claim 1, wherein
a first electrical resistance between the first electrode and the first counter electrode is configured to change according to a state of a first detection target.

12. The method for manufacturing the sensor according to claim 2, wherein
the first process further includes forming a second structure on the base,
the second structure includes:
a second electrode;
a second counter electrode;
a second layer-shaped portion provided between the base and the second electrode and between the base and the second counter electrode; and
a second sacrificial layer provided between the base and the second layer-shaped portion,
the second process includes forming a second metal oxide layer being in contact with the second electrode and the second counter electrode,
the sacrificial layer removal process further includes removing the second sacrificial layer,
the third process further includes forming a second member on the second metal oxide layer,
the second member includes a second element and a second material,
the sacrificial layer removal process includes removing at least a part of the second material, and
the second element is different from the first element.

13. The method for manufacturing the sensor according to claim 1, wherein
the treatment in the atmosphere including the oxygen plasma includes oxygen ashing.

14. The method for manufacturing the sensor according to claim 1, wherein
the second process includes forming the first metal oxide layer by sputtering.

15. The method for manufacturing the sensor according to claim 1, wherein
the first metal oxide layer includes an oxide including at least one selected from the group consisting of calcium, strontium, barium, and radium, and
the first metal oxide layer further includes carbon.

16. The method for manufacturing the sensor according to claim 1, wherein
the first structure further includes a first fixed portion fixed to the base, and
after the sacrificial layer removal process, the first fixed part supports the first layer-shaped portion.

17. The method for manufacturing the sensor according to claim 16, wherein
the first structure further includes a first counter fixed portion fixed to the base,
the first counter fixed portion supports the first layer-shaped portion after the sacrificial layer removal process,
the first structure further includes:
a first connecting portion provided between the first fixed portion and the first layer-shaped portion; and
a first counter connecting portion provided between the first counter fixed portion and the first layer-shaped portion.

18. A sensor, comprising:
a base;
a first element portion; and
a second element portion,
the first element portion including:
a first member including a first element,
a first structure provided between the base and the first member; and
a first metal oxide layer provided between the first structure and the first member,
the first structure including:
a first electrode and a first counter electrode provided between the base and the first member;
a first layer-shaped portion provided between the base and the first electrode and between the base and the first counter electrode,
a first gap being provided between the base and the first layer-shaped portion,
the first metal oxide layer being in contact with the first electrode and the first counter electrode,
the second element portion including:
a second member including a second element,
a second structure provided between the base and the second member; and
a second metal oxide layer provided between the second structure and the second member,
the second structure including:
a second electrode and a second counter electrode provided between the base and the second member; and
a second layer-shaped portion provided between the base and the second electrode and between the base and the second counter electrode,
a second gap being provided between the base and the second layer-shaped portion,
the second metal oxide layer being in contact with the second electrode and the second counter electrode, and
the second element being different from the first element.

19. The sensor according to claim 18, wherein
at least one of the first element and the second element includes at least one selected from the group consisting of platinum, palladium, titanium, rhodium, strontium, magnesium, manganese, zinc, iron, cobalt, nickel, bismuth, aluminum, selenium, germanium, and silicon, or constitutes at least one form selected from the group consisting of a single oxide, a perovskite-type metal oxide, a spinel-type metal oxide, and a hexaaluminate.

20. The sensor according to claim 18, wherein
a first electrical resistance between the first electrode and the first counter electrode is configured to change depending on a state of a first detection target.
